(19) United States
(12) Patent Application Publication
(10) Pub. No.: US 2012/0313113 A1
(43) Pub. Date: Dec. 13, 2012

(54) PHOTOVOLTAIC ORGANIC LIGHT EMITTING DIODES DEVICE AND MANUFACTURING METHOD THEREOF

(75) Inventors: Chien-Chih Chen, Taichung City (TW); Ching-Chiun Wang, Miaoli County (TW); Chih-Yung Huang, Taichung City (TW); Szu-Hao Chen, Changhua County (TW); Chan-Hsing Lo, Hsinchu County (TW); Chung-Ping Chiang, New Taipei City (TW)

(73) Assignee: INDUSTRIAL TECHNOLOGY RESEARCH INSTITUTE, Hsinchu (TW)

(21) Appl. No.: 13/228,449

(22) Filed: Sep. 9, 2011

(30) Foreign Application Priority Data
Jun. 7, 2011 (TW) 100119882

(51) Int. Cl. H01L 31/153; H01L 31/18

(52) U.S. Cl. 257/84; 438/24; 257/E31.1; 257/E31.128

(57) ABSTRACT

A photovoltaic organic light emitting diodes (PV-OLED) device and manufacturing method thereof are introduced. The PV-OLED device includes a substrate, a solar cell module, and a plurality of organic light emitting diodes. The solar cell module is disposed on a surface of the substrate. The organic light emitting diodes are disposed on the same surface of the substrate that the solar cell module is disposed on. The organic light emitting diode is electrically isolated from the solar cell module. The solar cell module can apply power to the organic light emitting diodes for emitting light.

### CROSS-REFERENCE TO RELATED APPLICATION

This application claims the priority benefit of Taiwan application serial no. 100119882, filed Jun. 7, 2011. The entirety of the above-mentioned patent application is hereby incorporated by reference herein and made a part of this specification.

### TECHNICAL FIELD

The disclosure relates to a photovoltaic organic light emitting diodes (PV-OLED) device integrating a solar cell module and a manufacturing method thereof.

### BACKGROUND

The global power consumption for illumination occupies about 19% of the overall power consumption. Traditional illumination apparatuses such as fluorescent lamps, light bulbs, or so on have reached their limits in terms of efficiency. With the shortage in energy supply, major countries focus on developing energy saving illumination apparatuses and owning patents of relevant technology to make profit in the next emerging market.

In addition, conventional cold cathode fluorescent lamps (CCFLs) have low color rendering property and are limited by RoHS mercury standard proposed by the European Union. CCFLs are thus gradually replaced by the solid state lighting (SSL) system having high illumination, high energy efficiency (>100 1 m/W), and long lifespan for environment protection and sustainability reasons.

Since the SSL system is estimated to have the capability of saving 50% of the energy and can meet the demands for energy saving, environment protection, and economy growth (3E), many countries are now actively developing mercury-free light sources such as organic light emitting diode (OLED), light emitting diode (LED), and the like. Having the characteristics of a large area planar light source and may be manufactured into a transparent OLED device with the material selected, OLED can further be utilized in windows of buildings.

### SUMMARY

A photovoltaic organic light emitting diodes (PV-OLED) device is introduced herein. The PV-OLD device includes a substrate, a solar cell module, and an organic light emitting diode. The solar cell module and the organic light emitting diode are disposed on the same surface of the substrate. The solar cell module is electrically isolated from the organic light emitting diode.

A method of manufacturing a PV-OLED device is further introduced herein. The method includes (a) providing a plurality of planar evaporation sources, each of the planar evaporation sources having an evaporation source substrate and an evaporation material formed on a surface of the evaporation source substrate; (b) heating a portion of the planar evaporation sources to evaporate the evaporation material of each of the heated planar evaporation sources on a surface of a substrate to form a first multi-layer structure; (c) removing a portion of the first multi-layer structure to form a solar cell module; (d) heating a portion of the planar evaporation sources to evaporate the evaporation material of each of the heated planar evaporation sources on the surface of the substrate to form a second multi-layer structure;(e) removing a portion of the second multi-layer structure to form an organic light emitting diode, where steps (b)-(c) are performed before step (d) or after step (e), and the organic light emitting diode is electrically isolated from the solar cell module.

A method of manufacturing a PV-OLED device is further introduced herein. The method includes (a) providing a planar evaporation source constituted by a plurality of linear evaporation sources, each of the linear evaporation sources having a first chamber and a second chamber connected to each other; (b) passing at least one evaporation gas into the first chamber and mixing the evaporation gas by natural convection and jetting the evaporation gas from each of the linear evaporation sources to a surface of a substrate by forced convection; (c) repeating step (b), the evaporation gas used in each repeating step is the same or different gas, until a first multi-layer structure is formed on the surface of the substrate; (d) removing a portion of the first multi-layer structure to form a solar cell module; (e) repeating step (b), wherein the evaporation gas used in each repeating step is the same or different gas, until a second multi-layer structure is formed on the same surface of the substrate; (f) removing a portion of the second multi-layer structure to form an organic light emitting diode, where steps (c)-(d) are performed before step (e) or after step (f) and the organic light emitting diode is electrically isolated from the solar cell module.

In light of the foregoing, the PV-OLED device integrating the solar cell module and the organic light emitting diode is made by manufacturing the solar cell module and the organic light emitting diode simultaneously on one surface of the same substrate. Thus, the PV-OLED device can be utilized in windows directly, so that the buildings can adopt daylight illumination during daytime while using the solar cell to absorb ultraviolet light in sunlight.

When integrated with the energy storage system, the PV-OLED device can apply the organic light emitting diodes for illumination at night or when the illumination is low to meet the demands of low power consumption or even zero power consumption.

Moreover, a flat/uniform evaporated surface is accomplished in the disclosure by using the planar evaporation source so as to ensure the uniformity of the slits in the solar cell module and the organic light emitting diodes.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A is a schematic top view illustrating a photovoltaic organic light emitting diodes (PV-OLED) device according to a first exemplary embodiment.

FIG. 1B is a schematic cross-sectional diagram taken along line B-B′ in FIG. 1A.

FIG. 2 is a schematic cross-sectional diagram of a PV-OLED device according to a second exemplary embodiment.

FIG. 3 is a three-dimensional (3D) diagram showing a flowchart of manufacturing a PV-OLED device according to a third exemplary embodiment.

FIG. 4A and FIG. 4B are two examples of a planar evaporation source in the third exemplary embodiment.

FIG. 5 is a schematic diagram of the planar evaporation source in the third exemplary embodiment carrying out continuous evaporations.

FIG. 6A is a 3D schematic diagram of a linear evaporation source according to a fourth exemplary embodiment.

FIG. 6B is a schematic cross-sectional view taken along line B-B in FIG. 6A.

FIG. 7 displays a planar evaporation source constituted by the linear evaporation source in FIG. 6A.

### DETAILED DESCRIPTION OF DISCLOSED EMBODIMENTS

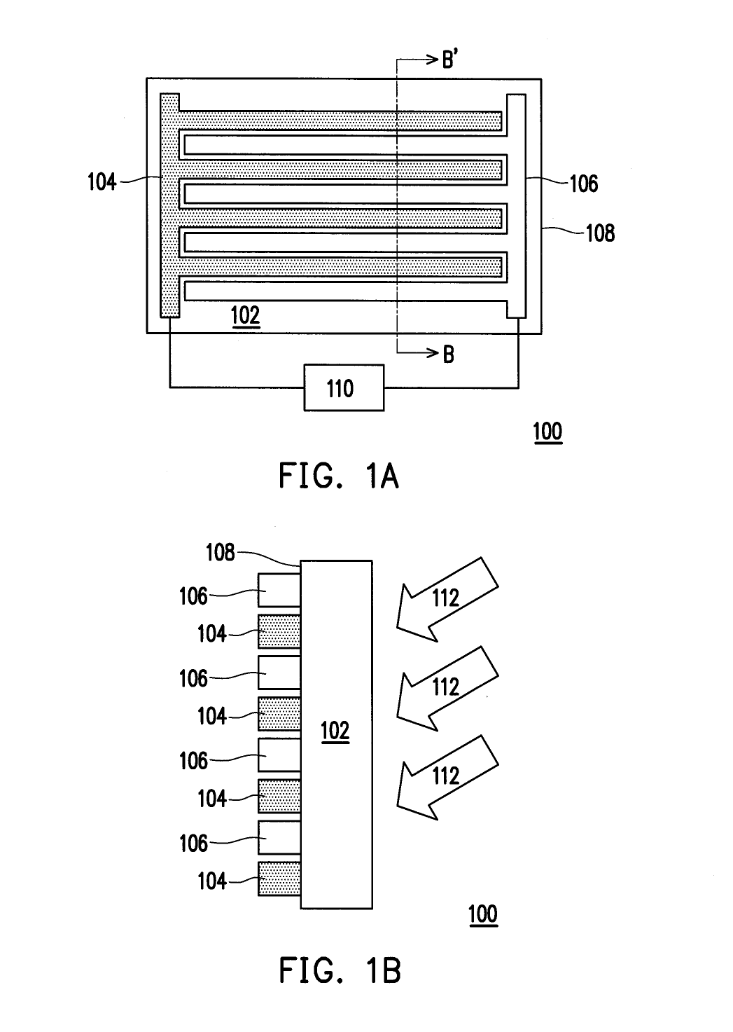

FIG. 1A is a schematic top view illustrating a photovoltaic organic light emitting diodes (PV-OLED) device according to a first exemplary embodiment. FIG. 1B is a schematic cross-sectional diagram taken along line B-B′ in FIG. 1A.

Referring to FIGS. 1A and 1B, a PV-OLED device 100 of the present exemplary embodiment includes a substrate 102, a solar cell module 104, and an organic light emitting diode 106. The substrate is a light transmissive substrate, for example.

The solar cell module 104 and the organic light emitting diode 106 are disposed on a same surface 108 of the substrate 102. The solar cell module 104 is electrically isolated from the organic light emitting diode 106. For example, The solar cell module 104 and the organic light emitting diode 106 do not contact each other.

Further, an energy storage system 110 connecting the solar cell module 104 and the organic light emitting diode 106 is disposed.

When a light beam 112 irradiates the PV-OLED device 100, the solar cell module 104 generates an electric power from the irradiation and transmits the electric power to the energy storage system 110 or directly to the organic light emitting diode 106 for illumination.

In FIGS. 1A and 1B, the solar cell module 104 and the organic light emitting diode 106 are merely illustrated in schematic diagrams; however, these two elements can be manufactured using conventional technology in practice.

For example, a thin film solar cell module, a crystalline silicon solar cell module, or other suitable solar cell modules can be adopted as the solar cell module 104; a transparent organic light emitting diode can be adopted as the organic light emitting diode 106.

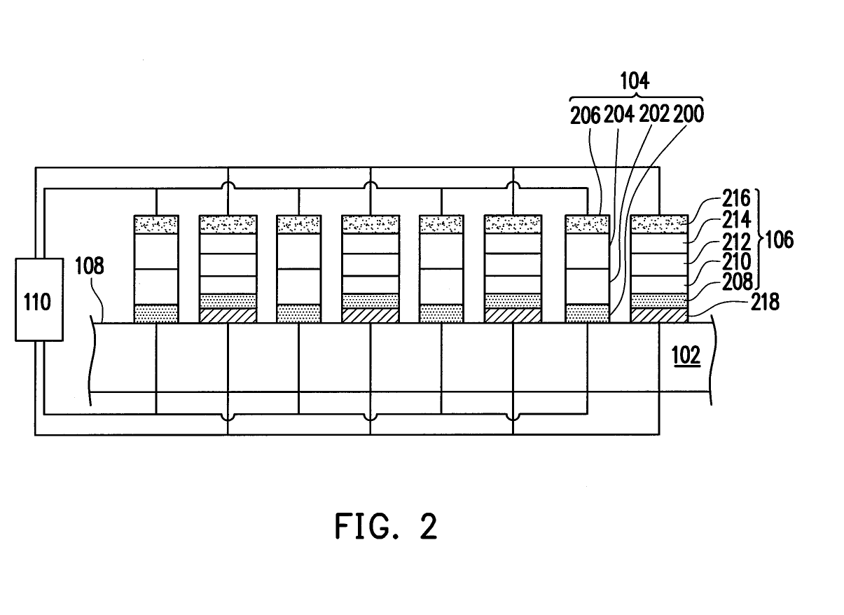

FIG. 2 is a schematic cross-sectional diagram of a PV-OLED device according to a second exemplary embodiment. Herein, identical devices or elements are denoted with the same notations as those in the first exemplary embodiment.

Referring to FIG. 2, the solar cell module 104 of the present exemplary embodiment is constituted by a transparent negative electrode 200, an N-type semiconductor 202, a P-type semiconductor 204, and a transparent positive electrode 206. The organic light emitting diode 106 is constituted by a transparent cathode 208, a hole transmission layer 210, a light emitting layer 212, an electron transmission layer 214, and an anode 216. The solar cell module 104 and the organic light emitting diode 106 are manufactured on the same surface 108. The transparent negative electrode 200 and the transparent anode 208 can thus be a conductive material layer plated on the surface 108 of the substrate 102 in a single step during the manufacture, where the conductive material layer is patterned through a photolithography etching process to result in separate electrodes on the solar cell module 104 and the organic light emitting diode 106. Additionally, a diffusion refractor layer 218 is disposed between the surface 108 of the substrate 102 and the organic light emitting diode 106 to reflect the light emitted by the organic light emitting diode 106. A material of the diffusion refractor layer 218 is a material capable of transmitting light and having reflectivity, such as TiO₂, SiO₂, and the like, for example. The PV-OLED device of the present exemplary embodiment further includes the energy storage system 110 connecting the solar cell module 104 and the organic light emitting diode 106 to store the electric power generated by the solar cell module 104 or supply the electric power generated by the solar cell module 104 to the organic light emitting diode 106.

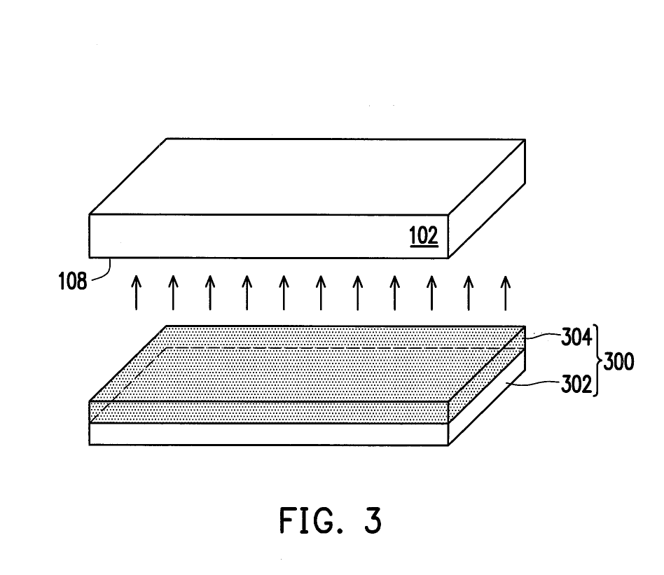

FIG. 3 is a three-dimensional (3D) diagram showing a flowchart of manufacturing a PV-OLED device according to a third exemplary embodiment.

In FIG. 3, an evaporation of a surface 108 of a substrate 102 performed by a single planar evaporation source 300 is shown. The planar evaporation source 300 includes an evaporation source substrate 302 and an evaporation material 304 formed on a surface of the evaporation source substrate 302. The surface of the evaporation source substrate 302 is a smooth surface in this exemplary embodiment, but the disclosure is limited herein. That is, the surface of the evaporation source substrate 302 may be a rough surface. When heating the planar evaporation source 300, the heated evaporation material 304 is evaporated on the substrate 102, so that the substrate 102 undergoes continuous evaporations with a plurality of planar evaporation sources having different evaporation materials to form a multi-layer structure (not shown).

For instance, when forming the solar cell module 104 and the organic light emitting diode 106 shown in FIG. 2, the planar evaporation source 300 can be applied to continuously form a multi-layer structure constituting the solar cell module 104 (or the organic light emitting diode 106). A portion of the multi-layer structure is then removed to form the solar cell module 104 (or the organic light emitting diode 106). Moreover, the sequence of forming the solar cell module 104 and the organic light emitting diode 106 can be reversed as long as the organic light emitting diode 106 is electrically isolated from the solar cell module 104.

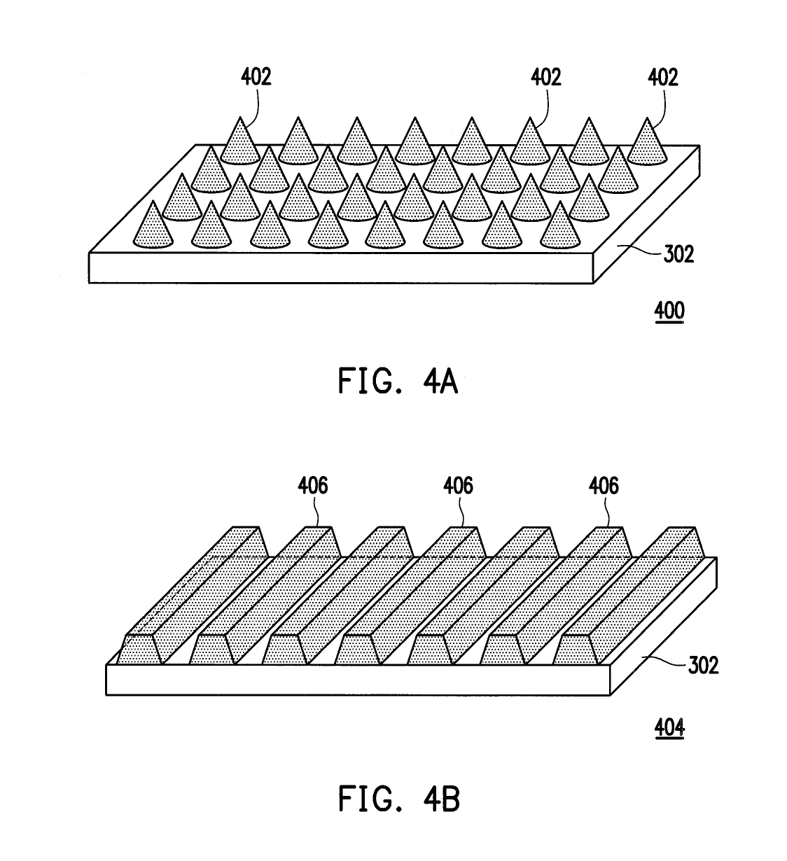

In FIG. 3, the evaporation material 304 of the planar evaporation source 300 is distributed and arranged in planes. However, the present exemplary embodiment is not limited thereto and an evaporation source of any shape can be used as long as the evaporation source has a flat top and is capable of forming a flat/uniform evaporated surface. For example, an evaporation material 402 of a planar evaporation source 400 depicted in FIG. 4A is arranged in dots; an evaporation material 406 of a planar evaporation source 404 depicted in FIG. 4B is arranged in lines.

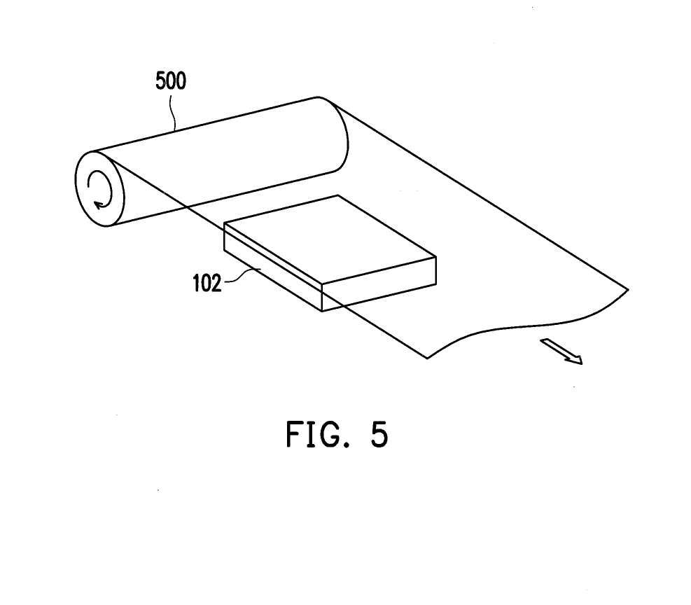

Moreover, the evaporation source substrate 400 is a flexible material which can be coiled to form a planar evaporation source coiled material 500 as shown in FIG. 5. Thus, continuous evaporations of the substrate 102 are carried out by continuously sending or intermittently feeding the planar evaporation source coiled material 500.

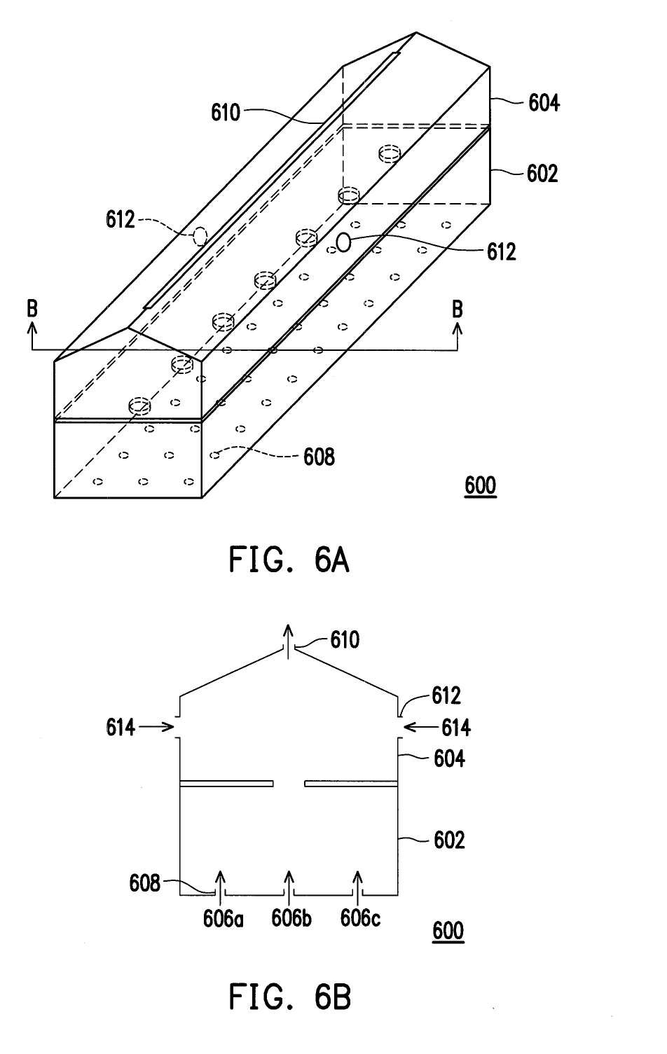

FIG. 6A is a 3D schematic diagram of a linear evaporation source according to a fourth exemplary embodiment.

FIG. 6B is a schematic cross-sectional view taken along line B-B in FIG. 6A.

Referring to FIGS. 6A and 6B, a single linear evaporation source 600 having a first chamber 602 and a second chamber 604 connected to each other is illustrated. When a plurality of evaporation gases 606a-c is passed into the first chamber 602 through a plurality of openings 608, the evaporation gases 606a-c are mixed by natural convection. The evaporation gases 606a-c are then jetted from an opening 610 of the linear evaporation source 600 by forced convection in the second chamber 604. The evaporation gases 606a-c used in each evaporation can be the same or different gas. For example, the same evaporation gas such as DPASN can be used independently to produce blue light; different evaporation gases such as DPASN doped with 4 wt % ER53 can be adopted simultaneously to produce white light.

When the openings 608 are critical orifices, the mass flow rate of each of the components can be adjusted and the amount of gas in each of the openings 608 can be integrated. The forced convection can be generated by passing a gas 614 from a plurality of openings 612 disposed on two sides of the second chamber 604. Moreover, when the opening 610 of the second chamber 604 is designed to be a critical orifice, as the size reduction of the opening 610 leads to lower pressure and faster speed, the change from normal pressure to vacuum pressure can be buffered. Additionally, the second chamber 604 has a taper design as depicted in FIG. 6 and can further prevent the gases (606a-c and 614) from generating vortex flows on the two sides after entering the critical orifices, so that the gases pause and evaporate on the two sides of the second chamber 604.

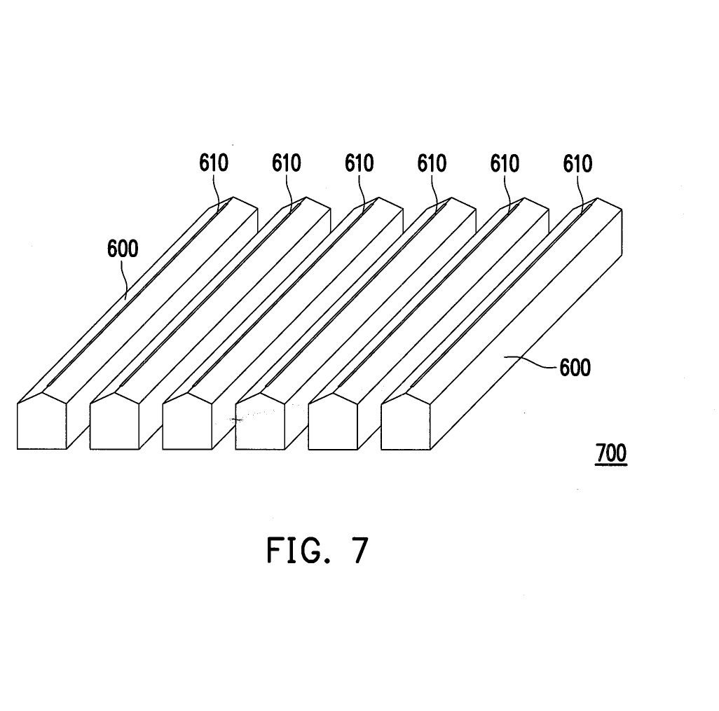

FIG. 7 displays a planar evaporation source 700 constituted by a plurality of linear evaporation sources 600. Here, the openings 610 of each of the linear evaporation sources 600 all face the same surface. Consequently, a substrate (not shown) can be disposed on the planar evaporation source 700 to undergo a plurality of evaporations for a multi-layer structure. With the step of removing a portion of the multi-layer structure, the solar cell module 104 (or the organic light emitting diode 106) can be formed as illustrated in the third exemplary embodiment. Moreover, the sequence of forming the solar cell module 104 and the organic light emitting diode 106 can be reversed as long as the organic light emitting diode 106 is electrically isolated from the solar cell module 104.

In FIG. 7, the linear evaporation sources 600 of the planar evaporation source 700 are distributed on an entire surface. However, the present exemplary embodiment is not limited thereto and an evaporation source of any shape can be used as long as the evaporation source is capable of forming a flat and highly uniformed evaporated surface.

In summary, since the PV-OLED device of the disclosure integrates the solar cell module and the organic light emitting diode, the PV-OLED device can thus be applied in windows directly, so that the buildings can have daylight illumination during daytime while using the solar cell to absorb ultraviolet light in sunlight. Furthermore, when integrating the energy storage system, the PV-OLED device of the disclosure can use the organic light emitting diodes for illumination at night or when the illumination is low. Also, the disclosure utilizes the planar evaporation source to form the flat/uniform multi-layer solar cell module and organic light emitting diode, such that the solar cell module and the organic light emitting diode can be manufactured on a single surface simultaneously.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A photovoltaic organic light emitting diodes device, comprising:
a substrate;
a solar cell module disposed on a surface of the substrate; and
an organic light emitting diode disposed on the surface of the substrate, wherein the organic light emitting diode is electrically isolated from the solar cell module.

2. The photovoltaic organic light emitting diodes device as claimed in claim 1, wherein the organic light emitting diode is a transparent organic light emitting diode.

3. The photovoltaic organic light emitting diodes device as claimed in claim 1, wherein the solar cell module is a thin film solar cell module.

4. The photovoltaic organic light emitting diodes device as claimed in claim 1, further comprising a diffusion refractor layer sandwiched between the surface of the substrate and the organic light emitting diode to reflect a light emitted by the organic light emitting diode.

5. The photovoltaic organic light emitting diodes device as claimed in claim 1, further comprising an energy storage system connecting the solar cell module and the organic light emitting diode to store energy or supply an electric power generated by the solar cell module to the organic light emitting diode.

6. A method of manufacturing a photovoltaic organic light emitting diodes device, the method comprising:
a) providing a plurality of planar evaporation sources, each of the planar evaporation sources having an evaporation source substrate and an evaporation material formed on a surface of the evaporation source substrate;
b) heating a portion of the planar evaporation sources to evaporate the evaporation material of each of the heated planar evaporation sources on a surface of a substrate to form a first multi-layer structure;
c) removing a portion of the first multi-layer structure to form a solar cell module;
d) heating a portion of the planar evaporation sources to evaporate the evaporation material of each of the heated planar evaporation sources on the surface of the substrate to form a second multi-layer structure; and
e) removing a portion of the second multi-layer structure to form an organic light emitting diode, wherein
steps b)-c) are performed before step d) or after step e), and the organic light emitting diode is electrically isolated from the solar cell module.

7. The method of manufacturing the photovoltaic organic light emitting diodes device as claimed in claim 6, wherein the evaporation material of each of the planar evaporation sources is distributed and arranged in dots, lines, or planes.

8. The method of manufacturing the photovoltaic organic light emitting diodes device as claimed in claim 6, wherein the surface of the evaporation source substrate is a smooth surface or a rough surface.

9. The method of manufacturing the photovoltaic organic light emitting diodes device as claimed in claim 6, wherein the evaporation source substrate is a flexible material.

10. The method of manufacturing the photovoltaic organic light emitting diodes device as claimed in claim 9, wherein the evaporation source substrate is coiled to form a planar evaporation source coiled material so as to carry out continuous evaporations by continuously sending or intermittently feeding the planar evaporation source coiled material.

11. A method of manufacturing a photovoltaic organic light emitting diodes device, the method comprising:
a) providing a planar evaporation source constituted by a plurality of linear evaporation sources, each of the linear evaporation sources having a first chamber and a second chamber connected to each other;
b) passing at least one evaporation gas into the first chamber and mixing the at least one evaporation gas by natural convection and jetting the at least evaporation gas from each of the linear evaporation sources to a surface of a substrate by forced convection;
c) repeating step b), wherein the at least one evaporation gas used in each repeating step is the same or different gas, until a first multi-layer structure is formed on the surface of the substrate;
d) removing a portion of the first multi-layer structure to form a solar cell module;
e) repeating step b), wherein the at least one evaporation gas used in each repeating step is the same or different gas, until a second multi-layer structure is formed on the surface of the substrate; and
f) removing a portion of the second multi-layer structure to form an organic light emitting diode, wherein
steps c)-d) are performed before step e) or after step f) and the organic light emitting diode is electrically isolated from the solar cell module.

12. The method of manufacturing the photovoltaic organic light emitting diodes device as claimed in claim 11, wherein the at least one evaporation gas is passed into the first chamber through at least one first critical orifice.

13. The method of manufacturing the photovoltaic organic light emitting diodes device as claimed in claim 11, wherein the at least one evaporation gas in the second chamber is jetted through a second critical orifice.
